(19) United States
(12) Patent Application Publication
(10) Pub. No.: US 2025/0380467 A1
(43) Pub. Date: Dec. 11, 2025

(54) TRENCH BASED SEMICONDUCTOR DEVICES WITH HETEROJUNCTION GATE

(71) Applicant: Wolfspeed, Inc., Durham, NC (US)

(72) Inventors: Rahul R. Potera, Apex, NC (US); Sei-Hyung Ryu, Cary, NC (US)

(21) Appl. No.: 18/738,646

(22) Filed: Jun. 10, 2024

(51) Int. Cl. H01L 29/80; H01L 29/16; H01L 29/66; H01L 29/78

(52) U.S. Cl. CPC H10D 30/801; H10D 30/0297; H10D 30/0516; H10D 30/668; H10D 62/8325

(57) ABSTRACT

A semiconductor device includes a drift layer including silicon carbide and having a first conductivity type, a channel layer on the drift layer, the channel layer including silicon carbide and having the first conductivity type, and a source layer on the channel layer, the source layer including silicon carbide and having the first conductivity type. The device includes first and second trenches extending through the source layer and at least partially into the channel layer. The first and second trenches define a mesa therebetween having a mesa sidewall adjacent the channel layer. A heterojunction layer is in the first trench. The heterojunction layer includes a semiconductor material having a second conductivity type opposite the first conductivity type, wherein the heterojunction layer forms a PN heterojunction with silicon carbide.

### TECHNICAL FIELD

The present disclosure relates to semiconductor devices and, more particularly, to power semiconductor devices having gate resistors.

### BACKGROUND

A wide variety of power semiconductor devices are known in the art including, for example, power Junction Field Effect Transistors (“JFETs”), power Metal Oxide Semiconductor Field Effect Transistors (“MOSFETs”), Insulated Gate Bipolar Transistors (“IGBTs”) and various other devices. These power semiconductor devices are often fabricated from wide bandgap semiconductor materials. Herein, the term “wide bandgap semiconductor” encompasses any semiconductor having a bandgap of at least 1.4 eV. Power semiconductor devices are designed to selectively block or pass large voltages and/or currents. For example, in the blocking state, a power semiconductor device may be designed to sustain hundreds or thousands of volts of electric potential.

Power semiconductor devices having high power ratings are most typically fabricated using silicon carbide, as silicon carbide has a number of advantageous characteristics including, for example, a high electric field breakdown strength, high thermal conductivity, high electron mobility, high melting point and high-saturated electron drift velocity. A conventional silicon carbide-based power semiconductor device typically has a silicon carbide substrate, such as a silicon carbide wafer having a first conductivity type (e.g., an n-type substrate), on which a silicon carbide epitaxial layer structure is formed which may have both first and second conductivity type layers and/or regions. Herein, the terms “first conductivity type” and “second conductivity type” are used to indicate either n-type or p-type, where the first and second conductivity types are different. Thus, if a first region of a device has a first conductivity type and a second region of the device has a second conductivity type, this means either that the first region has n-type conductivity and the second region has p-type conductivity or, alternatively, that first region has p-type conductivity and the second region has n-type conductivity.

The epitaxial layer structure of most power semiconductor devices includes a drift region and an “active region” that is formed on and/or in the drift region. The active region acts as a main junction for blocking voltage during off-state operation (also referred to as “reverse bias” or “reverse blocking” operation) and current flows through the active region during on-state operation (also referred to as “forward bias” operation). Most power semiconductor devices also have an edge termination region adjacent the active region. The edge termination region is designed to spread the electric fields during reverse blocking operation out over a greater area in order to reduce electric field crowding effects that would otherwise occur along the outer edges of the active region. One or more power semiconductor devices may be formed on the wafer, and each power semiconductor device will typically have its own edge termination region. After the epitaxial layer(s) is/are grown on the wafer and fully processed, the wafer may be diced to separate the individual edge-terminated power semiconductor devices if multiple devices are formed on the same wafer (or other substrate). The power semiconductor devices may have a unit cell structure in which the active region of each power semiconductor device includes a large number of individual cells that are disposed in parallel to each other and that together function as a single power semiconductor device.

A vertical JFET is a three terminal device that has gate, drain and source terminals that are formed on a semiconductor layer structure, which typically comprises a semiconductor substrate with epitaxial layers formed thereon. Source regions that are electrically connected to the source terminal and a drain region that is electrically connected to the drain terminal may be formed in the semiconductor layer structure. A plurality of channel regions are interposed in the semiconductor layer structure between the source regions and the drain region. A gate structure of the vertical JFET may include, for example, a gate bond pad that serves as the gate terminal, a gate pad that is connected to the gate bond pad, a plurality of gate contacts, and one or more gate buses and/or gate contacts that electrically connect the gate pad to the gate contacts. The gate contacts are disposed adjacent the respective channel regions. Power JFETs are typically normally-on devices, meaning that a JFET conducts current when a voltage of 0 volts is applied to the gate structure.

### SUMMARY

A semiconductor device according to some embodiments includes a drift layer including silicon carbide and having a first conductivity type, a channel layer on the drift layer, the channel layer including silicon carbide and having the first conductivity type, and a source layer on the channel layer, the source layer including silicon carbide and having the first conductivity type. The device includes first and second trenches extending through the source layer and at least partially into the channel layer. The first and second trenches define a mesa therebetween having a mesa sidewall adjacent the channel layer. A heterojunction layer is in the first trench. The heterojunction layer includes a semiconductor material having a second conductivity type opposite the first conductivity type, wherein the heterojunction layer forms a PN heterojunction with silicon carbide.

The heterojunction layer may be on a bottom of the first trench. In some embodiments, the heterojunction layer may be on a sidewall of the first trench adjacent the mesa. The heterojunction layer may form a PN heterojunction with the channel layer.

The heterojunction layer may include nickel oxide or polysilicon. The heterojunction layer may include an amorphous semiconductor material. The heterojunction layer may include nickel oxide and may have a thickness of about 100 nanometers of about 5000 nanometers.

The semiconductor device may further include a dielectric spacer on a sidewall of the source layer above the heterojunction layer.

The heterojunction layer may have a doping concentration of about 1E17 cm-3 to about 1E20 cm-3.

The semiconductor device may further include an implanted gate region in the mesa sidewall of the mesa adjacent the channel layer, wherein the implanted gate region is contacts the heterojunction layer and forms a PN junction with the channel layer.

A semiconductor device according to some embodiments includes a drift layer including silicon carbide and having a first conductivity type, a channel layer on the drift layer, the channel layer including silicon carbide and having the first conductivity type, a source layer on the channel layer, the source layer including silicon carbide and having the first conductivity type, and first and second trenches extending through the source layer, the channel layer and into the drift layer. The first and second trenches define a mesa having a mesa sidewall adjacent the channel layer. A heterojunction layer is in the first trench. The heterojunction layer includes a semiconductor material having a second conductivity type opposite the first conductivity type, and forms a PN heterojunction with silicon carbide.

The heterojunction layer may be on a bottom of the first trench. In some embodiments, the heterojunction layer may be on a sidewall of the first trench adjacent the mesa.

The heterojunction layer may form a PN heterojunction with the channel layer. In some embodiments, the heterojunction layer may form PN heterojunctions with both the drift layer and the channel layer.

The heterojunction layer may include nickel oxide or polysilicon. The heterojunction layer may include a sputtered layer. The heterojunction layer may include nickel oxide and may have a thickness of about 100 nanometers to about 5000 nanometers. The heterojunction layer may have a doping concentration of about 1E17 cm-3 to about 1E18 cm-3.

The semiconductor device may further include a gate ohmic contact on the heterojunction layer.

The mesa may include a first mesa, and the semiconductor device may further include a second mesa adjacent the first mesa, wherein the first mesa and the second mesa are separated by the first trench, wherein the heterojunction layer is on opposing sides of the first trench, and wherein a gate ohmic contact contacts top surfaces of the heterojunction layer on opposing sides of the first trench.

A method of forming a semiconductor device includes providing a semiconductor layer structure including a drift layer, a channel layer on the drift layer, and a source layer on the channel layer, wherein the drift layer, channel layer and source layer include silicon carbide and have a first conductivity type, forming first and second trenches extending through the source layer and at least partially into the channel layer, the first and second trenches defining a mesa between the trenches, the mesa having a mesa sidewall adjacent the channel layer, and forming a heterojunction layer in the first trench, wherein the heterojunction layer has a second conductivity type opposite the first conductivity type and forms a PN heterojunction with silicon carbide.

Forming the heterojunction layer on the mesa sidewall beneath the source layer may include forming a semiconductor layer at least partially on the source layer, and recessing the semiconductor layer beneath the source layer.

Recessing the semiconductor layer may include filling the trench with a photoresist material after forming the semiconductor layer and performing a wet etch of the semiconductor layer.

The method may further include forming a dielectric spacer on a sidewall of the source layer above the gate region.

The mesa may include a first mesa, and the method may further include forming a second mesa adjacent the first mesa, wherein the first mesa and the second mesa are separated by the first trench, wherein the heterojunction layer is on opposing sides of the trench, and wherein a gate ohmic contact contacts top surfaces of the heterojunction layer on opposing sides of the first trench.

### BRIEF DESCRIPTION OF DRAWINGS

FIG. 1 illustrates a cell of a vertical JFET semiconductor device.

FIG. 2 is a cross-sectional illustration of a vertical JFET semiconductor device according to some embodiments.

FIGS. 3A-3F illustrate operations for forming a vertical JFET semiconductor device according to some embodiments.

FIG. 4 is a cross-sectional illustration of a vertical JFET superjunction semiconductor device according to some embodiments.

FIGS. 5A-5F illustrate operations for forming a vertical JFET superjunction semiconductor device according to some embodiments.

FIG. 6 is a block diagram illustrating operations for forming a semiconductor device according to some embodiments.

FIGS. 7A and 7B are cross-sectional illustrations of vertical JFET semiconductor devices according to further embodiments.

FIGS. 8A and 8B are cross-sectional illustrations of vertical JFET superjunction semiconductor devices according to further embodiments.

### DETAILED DESCRIPTION

Embodiments of the inventive concepts are explained more fully with reference to the non-limiting aspects and examples that are described and/or illustrated in the accompanying drawings and detailed in the following description. It should be noted that the features illustrated in the drawings are not necessarily drawn to scale, and features of some embodiments may be employed with other aspects as the skilled artisan would recognize, even if not explicitly stated herein. Descriptions of well-known components and processing techniques may be omitted so as to not unnecessarily obscure the aspects of the disclosure. The examples used herein are intended merely to facilitate an understanding of ways in which the disclosure may be practiced and to further enable those of skill in the art to practice the aspects of the disclosure. Accordingly, the examples and aspects herein should not be construed as limiting the scope of the disclosure, which is defined solely by the appended claims and applicable law. Moreover, it is noted that like reference numerals represent similar parts throughout the several views of the drawings.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the another element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the another element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art.

Although a JFET device is sometimes referred to as a static induction transistor, the term JFET will be used in the description below. However, it will be appreciated that embodiments described herein may be applied to any device that uses a depletion region to modulate the conductivity of a channel in a mesa.

Although some embodiments are described in the context of a silicon carbide JFET device, it will be appreciated that aspects of the inventive concepts may be applicable to other types of devices that include mesas and trenches, such as vertical MOSFETs, insulated gate bipolar transistors (IGBTs) and other types of devices.

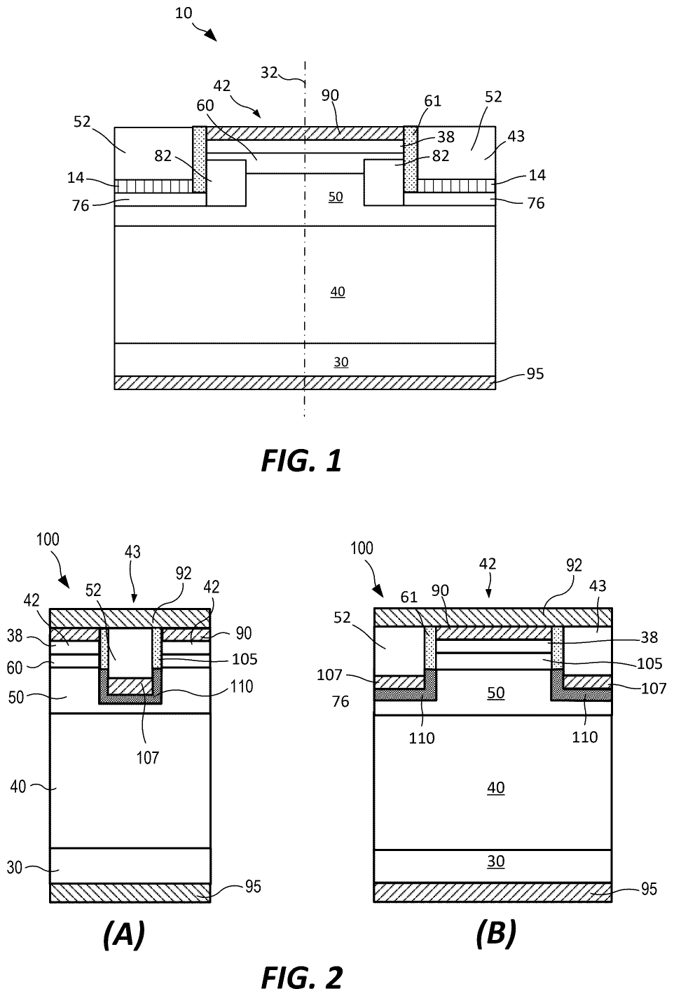

An n-channel vertical JFET structure 10 is shown in FIG. 1. The vertical JFET structure 1 includes an n+ substrate 30 on which an n-drift layer 40 is formed. An n-type channel layer 50 is on the drift layer 40, and an n+ source layer 60 is on the channel layer 50. The drift layer 40 may have a doping concentration of about 5E14 cm-3 to 1E17 cm-3. The channel layer 50 may have a doping concentration of about 5E15 cm-3 to 5E17 cm-3. An n++ source contact layer 38 is on the n+ source layer 60. A drain ohmic contact 95 is on the substrate 30, and a source ohmic contact 90 is on the source contact layer 38. The channel layer 50, source layer 60 and source contact layer 38 are provided as part of a mesa stripe 42 above the drift layer 40. Trenches 52 are formed in the structure 10 adjacent the mesa stripe 42.

A p+ gate region 82 is provided as part of the mesa stripe 42 adjacent the channel layer 50. A p++ gate contact region 76 is provided adjacent the gate region 82, and a gate ohmic contact, or gate finger, 14 is formed on the gate contact region 76 in the trenches 52 on opposite sides of the mesa stripe 42. To form the gate finger 14, a layer of metal, such as nickel (Ni), is deposited on the upper surfaces of the gate contact regions 76 and patterned appropriately. The metal is then annealed (for example, by being subjected to high temperature for a period of time) to form metal silicide layers on the upper surfaces of the gate contact regions 76, which provide ohmic contacts to the underlying layers.

An interlayer dielectric layer 43 is formed in the trenches 52 on the gate finger 14 and the gate contact region 76. The interlayer dielectric layer 43 may be formed, for example, from silicon oxide. In some embodiments, the interlayer dielectric layer 43 may be a borophosphosilicate glass (BPSG), which is a type of silicate glass that includes additives of both boron and phosphorus. Oxide/nitride spacer layers 61 are provided on sidewalls of the mesa stripe 42.

The vertical JFET unit cell structure 10 is symmetrical about the axis 32 and includes two gate regions 82 as part of the mesa stripe 42 on opposite sides of the channel layer 50.

The channel layer 50 of the vertical JFET structure 10 is formed within the mesa stripe 42 between the gate regions 82. The channel width is into the plane of FIG. 1, and the channel length is in the vertical direction from the source region 60 to the drift layer 40. Such a vertical JFET structure with a short channel length may also be called a static-induction transistor (SIT). In a SIT, the channel length is chosen based on a trade-off between low on-resistance in the on-state (short channel) and resistance to drain-induced barrier lowering (DIBL) in the off-state. A p-channel JFET may have a similar structure, but the conductivity types are reversed from those shown in FIG. 1.

In operation, conductivity between the source layer 60 and the substrate 30 is modulated by applying a reverse bias to the gate regions 82 relative to the source layer 60. To switch off an n-channel device such as the JFET structure 10, a negative gate-to-source voltage (or gate voltage) V_{GS} is applied to the gate regions 82. When no voltage is applied to the gate region 82, charge carriers can flow freely from the source layer 60 through the channel layer 50 and the drift layer 40 to the substrate 30.

One potential drawback to the structure shown in FIG. 1 is the need to form the gate contact regions 76 and gate regions 82 using p-type implants. In the structure shown in FIG. 1, the gate-channel PN junction is typically formed using high temperature implantation of p-type dopant atoms, such as aluminum. Such processes may be expensive and may also require a high temperature activation anneal process to be performed. Some embodiments described herein provide a SiC JFET semiconductor device structure that includes a heterojunction gate. A heterojunction gate may be formed via a deposition method such as sputtering, and the heterojunction gate may be p-type as deposited. Thus, the use of a heterojunction gate may obviate the need for the use of high temperature implants and/or an activation anneal step for forming the gate and gate contact regions of the device.

In particular, in some embodiments, a heterojunction may be formed between a layer of p-type non-SiC material and the channel layer 50. The layer of p-type non-SiC material forms a PN junction to silicon carbide on the channel layer 50. The layer of p-type non-SiC material may, for example, be a material such as p-type nickel oxide or p-type polysilicon. Such materials may be formed on silicon carbide by a method such as sputtering, which may be used to precisely control the thickness and/or doping level of the layer of non-SiC material that is applied.

Some further embodiments may use a heterojunction gate structure to form a SiC JFET superjunction device, as described in more detail below.

FIG. 2 illustrates a SiC JFET semiconductor device 100 according to some embodiments. In particular, FIG. 2(A) shows a SiC JFET semiconductor device 100 from a perspective centered on a trench 52, while FIG. 2(B) shows the SiC JFET semiconductor device 100 from a perspective centered on a mesa 42. The device 100 is similar to the SiC JFET device structure 10 shown in FIG. 1, except the device 100 includes a heterojunction layer 110 in the trenches 52. The heterojunction layer 110 is a semiconductor layer that forms a heterojunction with the semiconductor material of the channel layer 50. For example, when the channel layer 50 is formed of silicon carbide, the heterojunction layer 110 comprises a non-SiC semiconductor material. The heterojunction layer 110 is formed at the bottom of the trench 52 and may extend onto sidewalls of the mesa stripes 42 adjacent the channel layer 50. The heterojunction layer 110 has a conductivity type opposite the conductivity type of the channel layer 50 and forms a PN heterojunction with the channel layer 50. For example, the heterojunction layer 110 may include nickel oxide, polysilicon, or any other suitable material that can be doped with p-type dopants and that can form a PN heterojunction with n-type silicon carbide.

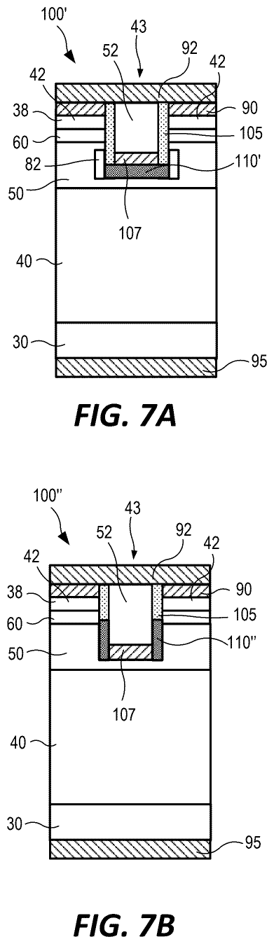

In some embodiments, the heterojunction layer 110 may not extend onto sidewalls of the trenches 52 or mesas 42 in some embodiments or bottoms of the trenches 52 in some embodiments. For example, brief reference is made to FIGS. 7A and 7B. FIG. 7A illustrates a SiC JFET device structure 100′ that includes a heterojunction layer 110′ that is formed primarily at the bottom of the trench 52 and that does not substantially extend onto sidewalls of the trench 52/mesas 42. In such a structure, sidewall implants of p-type dopants may be provided to form gate regions 82 on the sidewalls of the mesas 42, similar to the structure shown in FIG. 1. The sidewall gate regions 82 may form PN junctions with the channel layer 50 and may contact the heterojunction layer 110′.

Conversely, FIG. 7B illustrates a SiC JFET device structure 100″ that includes a heterojunction layer 110″ that is formed primarily on sidewalls of the trench 52/mesas 42, while the bottom of the trench 52 is substantially free of the heterojunction layer 110″.

Referring again to FIG. 2, an optional gate contact 107 may be formed on the heterojunction layer 110 to provide enhanced conduction to a gate electrode of the device 100. For example, the optional gate contact 107 may include nickel or nickel silicide. Sidewall spacers 105 are formed on sidewalls of the mesas 42 above the heterojunction layer 110.

The trench 52 is filled with the interlayer dielectric layer 43, and a source electrode 92 is formed over the device to provide electrical contact to the source contacts 90.

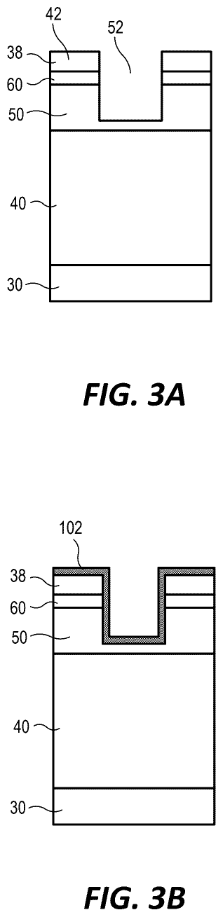

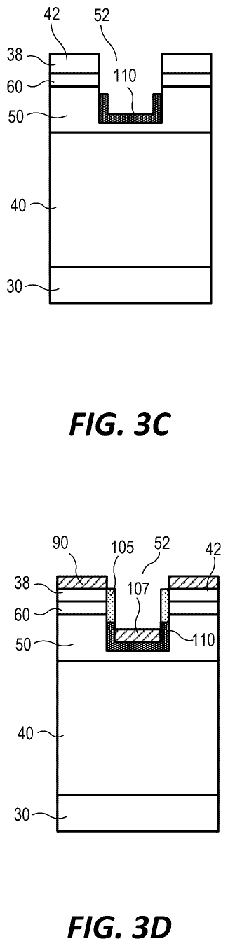

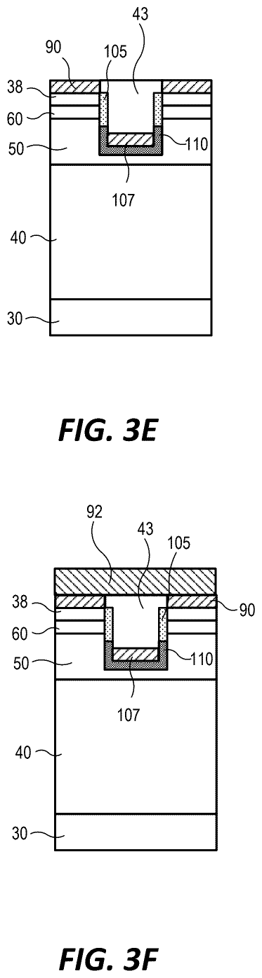

Operations for forming the device 100 are illustrated in FIGS. 3A to 3F. Referring to FIG. 3A, a semiconductor structure including a substrate 30, a drift layer 40, a channel layer 50, a source layer 60 and a source contact layer 38 is provided. Each of these layers is doped with a first conductivity type dopant, such as an n-type dopant. The drift layer 40 may have a doping concentration of about 5E14 cm-3 to 1E17 cm-3. The channel layer 50 may have a doping concentration of about 5E15 cm-3 to 5E17 cm-3. A plurality alternating mesa stripes 42 and trenches 52 is formed in the structure, for example by an isotropic etch process. The trenches 52 extend through the source contact layer 38 and the source layer 60 and into the channel layer 50.

It will be appreciated that the various layers and regions in the device 100 may be formed using various processes, including without limitation epitaxial deposition and/or ion implantation and annealing.

Referring to FIG. 3B, a layer of a non-SiC material 102 is formed on the upper surface of the structure. The layer of a non-SiC material 102 has a second conductivity type (e.g., p-type) and forms a PN heterojunction with the channel layer 50. The layer of non-SiC material 102 may be formed by an epitaxial deposition process, such as low pressure chemical vapor deposition (LPCVD) or a non-epitaxial deposition process, such as sputtering. For example, in some embodiments the layer of non-SiC material 102 may include nickel oxide, polysilicon, or any other suitable material that forms a PN heterojunction with the channel layer 50.

For deposition of nickel oxide, a sputtering process may be used to sputter nickel and an acceptor, such as aluminum, in an environment containing oxygen and an inert gas, such as argon. During the sputtering process, the partial pressure of oxygen may be controlled to obtain a desired concentration of acceptor dopants. For example, the partial pressure of oxygen may be controlled to provide an acceptor concentration of from about 1E17 cm-3 to 1E20 cm-3 using an Ar:O2 ratio of 20:1.

It will be appreciated that nickel oxide has a bandgap of about 3.4 to 4 eV, a projected critical field (EC) up to 5 MV/cm, and dielectric constant of 11.9, Nickel oxide can be conformally sputtered to form PN junctions on non-planar SiC structures.

The thickness of a nickel oxide layer 102 will be determined by acceptor concentration. It is anticipated that a thickness of about 250 nm to 500 nm may be suitable for the layer 102 to function as a gate and to provide appropriate charge balance.

Referring to FIG. 3C, the layer of non-SiC material 102 is etched back to a level below the source layer 60 to form a heterojunction layer 110 at the bottom of the trench 52 and on lower sidewalls of the mesa stripes 42 adjacent the channel layer 50. The non-SiC gate layer 10 forms a heterojunction PN junction with the channel layer 50.

A chemical mechanical polish (CMP) process may be used to remove the layer of non-SiC material 102 from upper surfaces of the mesa stripes 42. Alternatively or additionally, when the layer of non-SiC material 102 includes nickel oxide, the layer of non-SiC material 102 may be selectively etched back using an etch process, such as a buffered oxide etch (also referred to as a buffered HF or BHF, etch).

Referring to FIG. 3D, an oxide/nitride spacer layer 105 is formed on exposed portions of the sidewalls of the trench 52 above the heterojunction layer 110. Source ohmic contacts 90 are formed on the source contact region 38, for example, by a conventional silicide process to form nickel silicide contacts.

An optional gate ohmic contact 107 may be formed on the heterojunction layer 110. The optional gate ohmic contact 107 may be formed by a silicide process when the heterojunction layer 110 comprises a silicon-containing material, such as polysilicon.

Referring to FIG. 3E, an interlayer dielectric layer 43 of a material such as borophosphosilicate glass (BPSG) is formed in the trench 52 over the heterojunction layer 110 and the optional gate ohmic contact 107. The structure is then planarized to expose the source ohmic contacts 90.

Referring to FIG. 3F, a source contact 92 is then formed on the source ohmic contacts 90, and a drain ohmic contact 95 is formed on the substrate 30.

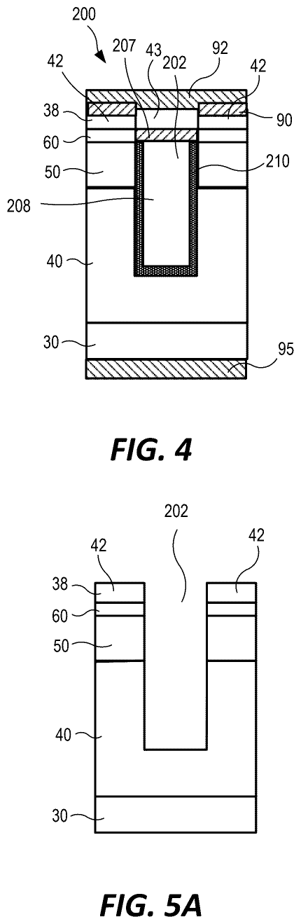

FIG. 4 illustrates a SiC JFET semiconductor device 200 having a superjunction structure according to some embodiments. The device 200 is similar to the SiC JFET device structure 200 shown in FIG. 2, except the device 200 includes a superjunction structure.

A superjunction structure is a structure used in semiconductor devices to enhance performance by reducing the on-resistance and increasing the breakdown voltage of the device. Superjunction structures may be employed in JFET devices as well as Metal-Oxide-Semiconductor Field Effect Transistors (MOSFETS) and Insulated-Gate Bipolar Transistors (IGBTs).

A superjunction structure includes alternating p-type and n-type semiconductor regions arranged vertically in the drift layer of the device. The charges in the p-type regions are balanced by the charges in the n-type regions, which allows the device to support high voltages without the need for heavily doped regions, which would otherwise increase on-resistance.

The presences of alternating vertical regions in the device, the electric field distribution within the device may be more uniform, which may enhance the breakdown voltage of the device.

Referring still to FIG. 4, the device 200 includes a plurality of alternating mesas 42 and trenches 202. The trenches 202 extend through the channel layer 50 and into the drift layer 40. The device 200 has a heterojunction layer 210 that is formed at the bottom of the trench 202 and on sidewalls of the mesa stripes 42 adjacent the channel layer 50 and adjacent the drift layer 40. The heterojunction layer 210 forms PN heterojunctions with both the channel layer 50 and the drift layer 40. Due to a low doping concentration in the drift layer 40 (e.g., less than about 2E17 cm-3), the heterojunction layer 210 depletes portions of the drift layer 40.

As noted above, the heterojunction layer 210 includes a p-type material that forms a PN heterojunction with the channel layer 50 and the drift layer 40. For example, the heterojunction layer 210 may include nickel oxide, polysilicon, or any other suitable material that can be doped with p-type dopants and that can form a PN junction with silicon carbide.

An optional gate ohmic contact 207 may be formed on the heterojunction layer 210 to provide enhanced conduction to a gate electrode of the device 200. For example, the optional gate ohmic contact 207 may include nickel or nickel silicide.

The trench 202 is filled with the insulation layer 208, and a source electrode 92 is formed over the device to provide electrical contact to the source contacts 90.

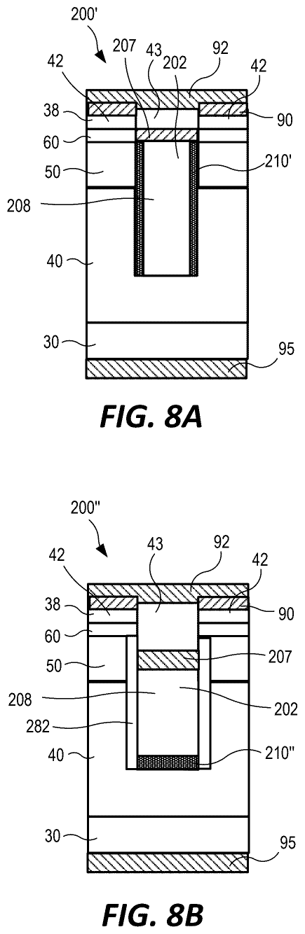

In some embodiments, the heterojunction layer 210 may only be on the bottoms of the trenches, or on the sidewalls of the trench/mesas, but not both. For example, brief reference is made to FIGS. 8A and 8B, which illustrates SiC JFET superjunction device structures 200′ and 200″. The device 200′ shown in FIG. 8A includes a heterojunction layer 210′ that is formed primarily on sidewalls of the trench 202/mesas 42, while the bottom of the trench 202 is substantially free of the heterojunction layer 210′.

In the device 200″ shown in FIG. 8B, a heterojunction layer 210″ is formed at the bottom of the trench 202, while p-type regions 282 are formed in the sidewalls of the trench 202/mesas 42 to provide the p-type superjunction regions and gate regions. A gate contact 207 is formed in the trench to contact the p+ regions 282. Although shown on the insulation layer 208, the gate ohmic contact 207 may be placed anywhere suitable within the trench 202 to provide electrical connection to the p-type gate regions 282.

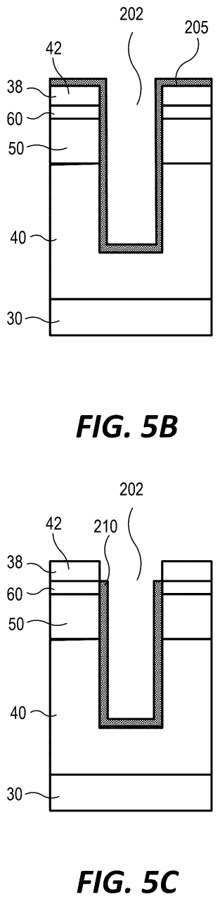

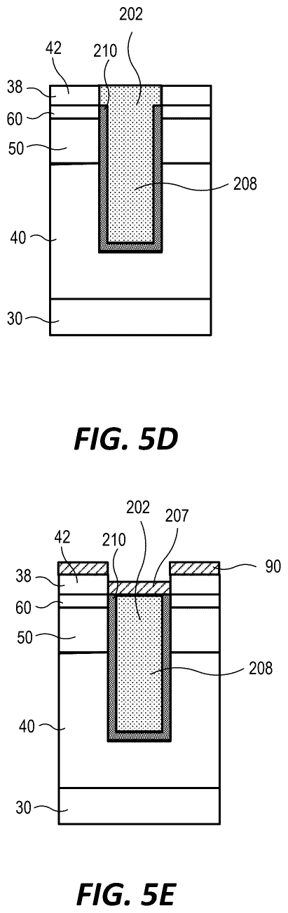

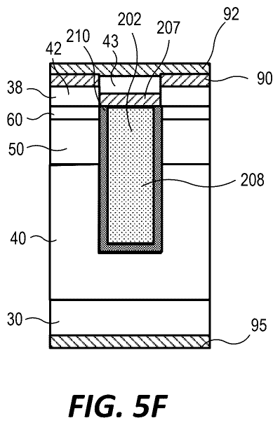

Operations for forming the device 200 are illustrated in FIGS. 5A to 5F. Referring to FIG. 5A, a semiconductor structure including a substrate 30, a drift layer 40, a channel layer 50, a source layer 60 and a source contact layer 38 is provided. Each of these layers is doped with a first conductivity type dopant, such as an n-type dopant. The drift layer 40 may have a doping concentration of about 5E14 cm-3 to 5E17 cm-3. The channel layer 50 may have a doping concentration of about 5E15 cm-3 to 1E18 cm-3.

A plurality alternating mesa stripes 42 and trenches 202 is formed in the structure, for example by an isotropic etch process. The trenches 202 extend through the source contact layer 38, the source layer 60, the channel layer 50 and into the drift layer 40.

Referring to FIG. 5B, a layer of a non-SiC material 205 is formed on the upper surface of the structure. The layer of non-SiC material 205 has a second conductivity type (e.g., p-type) and forms a PN heterojunction with the channel layer 50 and the drift layer 40. The layer of non-SiC material 205 may be formed by an epitaxial deposition process, such as LPCVD or a non-epitaxial deposition process, such as sputtering. For example, in some embodiments the layer of non-SiC material 205 may include nickel oxide, polysilicon, or any other suitable material that forms a PN heterojunction with the channel layer 50 and the drift layer 40.

For deposition of nickel oxide, a sputtering process may be used as described above with respect to FIG. 3B.

The thickness of the layer 205 will be determined by acceptor concentration. It is anticipated that a thickness of about 100 nm to 5000 nm may be suitable for the layer 205 to function as a gate and to provide appropriate charge balance in a superjunction structure.

Referring to FIG. 5C, the layer of non-SiC material 205 is etched back to a level below the source layer 60 to form a heterojunction layer 210 at the bottom of the trench 202 and on lower sidewalls of the mesa stripes 42 adjacent the channel layer 50 and the drift layer 40. The heterojunction layer 210 forms heterojunction PN junctions with the channel layer 50 and with the drift layer 40.

A chemical mechanical polish (CMP) process may be used to remove the layer of non-SiC material 102 from upper surfaces of the mesa stripes 42. Alternatively or additionally, when the layer of non-SiC material 102 includes nickel oxide, the layer of non-SiC material 102 may be selectively etched back using an etch process, such as a buffered oxide etch (also referred to as a buffered HF or BHF, etch).

Referring to FIG. 5D, an insulation layer 208 is formed in the trench 202 over the heterojunction layer 210. The insulation layer 208 may include silicon oxide and/or silicon oxynitride.

Referring to FIG. 5E, the insulation layer 208 is etched back or chemically-mechanically polished to expose upper surfaces of the heterojunction layer 210. Source contacts 90 are formed on the source contact regions 38. An optional gate ohmic contact 207 may be formed on the insulation layer 208 and on exposed surfaces of the heterojunction layer 210.

Referring to FIG. 5F, an interlayer dielectric layer 43 is formed above the insulation layer 208 and the optional gate ohmic contact 207, and a source contact 92 is formed on the source ohmic contacts 90, and a drain ohmic contact 95 is formed on the substrate 30.

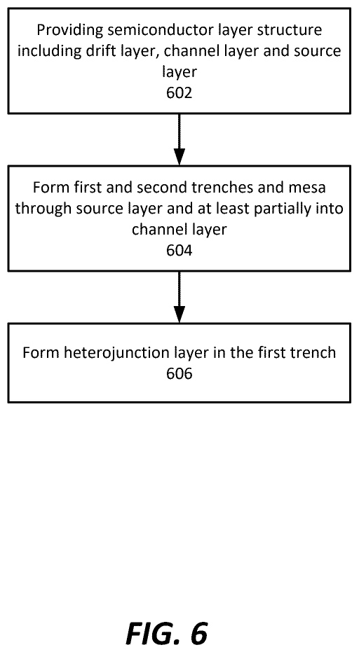

FIG. 6 is a block diagram illustrating operations for forming a semiconductor device according to some embodiments. In particular, A method of forming a semiconductor device includes providing a semiconductor layer structure including a drift layer, a channel layer on the drift layer, and a source layer on the channel layer (block 602). The drift layer, channel layer and source layer comprise silicon carbide and have a first conductivity type. The method further includes forming first and second trenches extending through the source layer and at least partially into the channel layer (block 604). The first and second trenches define a mesa between the trenches. The mesa includes a mesa sidewall adjacent the channel layer. A heterojunction layer is formed in the first trench (block 606). The heterojunction layer has a second conductivity type opposite the first conductivity type and forms a PN heterojunction with silicon carbide.

Forming the heterojunction layer on the mesa sidewall beneath the source layer may include forming a semiconductor layer at least partially on the source layer, and recessing the semiconductor layer beneath the source layer. Recessing the semiconductor layer may be performed by filling the trench with a photoresist material after forming the semiconductor layer and performing a wet etch of the semiconductor layer.

In some embodiments, a second mesa may be formed adjacent the first mesa, where the first mesa and the second mesa are separated by the first trench. The heterojunction layer is on opposing sides of the trench, and the gate ohmic contact contacts top surfaces of the semiconductor heterojunction layer on opposing sides of the first trench.

The inventive concepts have been described above with reference to the accompanying drawings, in which embodiments are shown. The inventive concepts may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. It will be understood that when an element or layer is referred to as being “on”, “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items. Like numbers refer to like elements throughout, except where expressly noted.

It will be understood that although the terms first and second are used herein to describe various regions, layers and/or elements, these regions, layers and/or elements should not be limited by these terms. These terms are only used to distinguish one region, layer or element from another region, layer or element. Thus, a first region, layer or element discussed below could be termed a second region, layer or element, and similarly, a second region, layer or element may be termed a first region, layer or element without departing from the scope of the present invention.

Relative terms, such as “lower” or “bottom” and “upper” or “top,” may be used herein to describe one element's relationship to another element as illustrated in the drawings. It will be understood that relative terms are intended to encompass different orientations of the device in addition to the orientation depicted in the drawings. For example, if the device in the drawings is turned over, elements described as being on the “lower” side of other elements would then be oriented on “upper” sides of the other elements. The exemplary term “lower” can, therefore, encompass both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The term “in electrically conductive contact” means that two elements are in direct or indirect contact in such a way that electrical current can flow from one element to another. At least part of the connection between the two elements may be electrically resistive.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises,” “comprising,” “includes” and/or “including,” when used herein, specify the presence of stated features, elements, and/or components, but do not preclude the presence or addition of one or more other features, elements, components, and/or groups thereof.

Embodiments of the inventive concepts are described herein with reference to cross-sectional illustrations that are schematic illustrations. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Thus, the regions illustrated in the figures are schematic in nature and their shapes are not intended to illustrate the actual shape of a region of a device and are not intended to limit the scope of the invention.

It will be understood that the embodiments disclosed herein can be combined. Thus, features that are pictured and/or described with respect to a first embodiment may likewise be included in a second embodiment, and vice versa.

While the above embodiments are described with reference to particular figures, it is to be understood that some embodiments of the present invention may include additional and/or intervening layers, structures, or elements, and/or particular layers, structures, or elements may be deleted. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

1. A semiconductor device, comprising:
a drift layer comprising silicon carbide and having a first conductivity type;
a channel layer on the drift layer, the channel layer comprising silicon carbide and having the first conductivity type;
a source layer on the channel layer, the source layer comprising silicon carbide and having the first conductivity type;
first and second trenches extending through the source layer and at least partially into the channel layer, the first and second trenches defining a mesa therebetween, the mesa having a mesa sidewall adjacent the channel layer; and
a heterojunction layer in the first trench, wherein the heterojunction layer comprises a semiconductor material having a second conductivity type opposite the first conductivity type, wherein the heterojunction layer forms a PN heterojunction with silicon carbide.

2. The semiconductor device of claim 1, wherein the heterojunction layer is on a bottom of the first trench.

3. The semiconductor device of claim 1, wherein the heterojunction layer is on a sidewall of the first trench adjacent the mesa.

4. The semiconductor device of claim 3, wherein the heterojunction layer forms a PN heterojunction with the channel layer.

5. The semiconductor device of claim 1, wherein the heterojunction layer comprises nickel oxide or polysilicon.

6. The semiconductor device of claim 1, further comprising a dielectric spacer on a sidewall of the source layer above the heterojunction layer.

7. The semiconductor device of claim 1, wherein the heterojunction layer comprises an amorphous semiconductor material.

8. The semiconductor device of claim 1, wherein the heterojunction layer comprises nickel oxide and has a thickness of about 100 nanometers to about 5000 nanometers.

9. The semiconductor device of claim 8, wherein the heterojunction layer has a doping concentration of about 1E17 cm-3 to about 1E20 cm-3.

10. The semiconductor device of claim 1, further comprising an implanted gate region in the mesa sidewall adjacent the channel layer, wherein the implanted gate region is contacts the heterojunction layer and forms a PN junction with the channel layer.

11. The semiconductor device of claim 1, further comprising a gate ohmic contact on the heterojunction layer.

12. The semiconductor device of claim 1, wherein the trench extends completely through the channel layer and into the drift layer and the channel layer.

13. A semiconductor device, comprising:
a drift layer comprising silicon carbide and having a first conductivity type;
a channel layer on the drift layer, the channel layer comprising silicon carbide and having the first conductivity type;
a source layer on the channel layer, the source layer comprising silicon carbide and having the first conductivity type;
first and second trenches extending through the source layer, the channel layer and into the drift layer, the first and second trenches defining a mesa therebetween, the mesa having a mesa sidewall adjacent the channel layer; and
a heterojunction layer in the first trench, wherein the heterojunction layer comprises a semiconductor material having a second conductivity type opposite the first conductivity type, and wherein the heterojunction layer forms a PN heterojunction with silicon carbide.

14. The semiconductor device of claim 13, wherein the heterojunction layer is on a bottom of the first trench.

15. The semiconductor device of claim 13 wherein the heterojunction layer is on a sidewall of the first trench adjacent the mesa.

16. The semiconductor device of claim 15, wherein the heterojunction layer forms a PN heterojunction with the channel layer.

17. The semiconductor device of claim 13, wherein the heterojunction layer forms PN heterojunctions with both the drift layer and the channel layer.

18. The semiconductor device of claim 16, wherein the heterojunction layer comprises nickel oxide or polysilicon.

19. The semiconductor device of claim 13, wherein the heterojunction layer comprises a sputtered layer.

20. The semiconductor device of claim 13, wherein the heterojunction layer comprises nickel oxide and has a thickness of about 100 nanometers to about 5000 nanometers.

21. The semiconductor device of claim 13, wherein the heterojunction layer has a doping concentration of about 1E17 cm-3 to about 1E18 cm-3.

22. The semiconductor device of claim 13, wherein the heterojunction layer contacts a bottom surface of the first trench.

23. The semiconductor device of claim 13, further comprising a gate ohmic contact on the heterojunction layer.

24. The semiconductor device of claim 13, wherein the mesa comprises a first mesa, the semiconductor device further comprising a second mesa adjacent the first mesa, wherein the first mesa and the second mesa are separated by the first trench, wherein the heterojunction layer is on opposing sides of the first trench, and wherein a gate ohmic contact contacts top surfaces of the heterojunction layer on opposing sides of the first trench.

25. A method of forming a semiconductor device, comprising:
providing a semiconductor layer structure including a drift layer, a channel layer on the drift layer, and a source layer on the channel layer, wherein the drift layer, channel layer and source layer comprise silicon carbide and have a first conductivity type;
forming first and second trenches extending through the source layer and at least partially into the channel layer, the first and second trenches defining a mesa between the trenches, the mesa having a mesa sidewall adjacent the channel layer; and
forming a heterojunction layer in the first trench, wherein the heterojunction layer has a second conductivity type opposite the first conductivity type and forms a PN heterojunction with silicon carbide.

26-36. (canceled)
